(19) United States
(12) Patent Application Publication
(10) Pub. No.: US 2014/0332959 A1
(43) Pub. Date: Nov. 13, 2014

(54) METHOD OF MANUFACTURING SEMICONDUCTOR DEVICE AND SEMICONDUCTOR DEVICE

(71) Applicants: Junichi Hamaguchi, Susono-shi (JP); Shuji Kodaira, Susono-shi (JP); Yuta Sakamoto, Susono-shi (JP); Akifumi Sano, Susono-shi (JP); Koukichi Kamada, Susono-shi (JP); Yoshiyuki Kadokura, Susono-shi (JP); Joji Hiroishi, Susono-shi (JP); Yukinobu Numata, Susono-shi (JP); Koji Suzuki, Susono-shi (JP)

(72) Inventors: Junichi Hamaguchi, Susono-shi (JP); Shuji Kodaira, Susono-shi (JP); Yuta Sakamoto, Susono-shi (JP); Akifumi Sano, Susono-shi (JP); Koukichi Kamada, Susono-shi (JP); Yoshiyuki Kadokura, Susono-shi (JP); Joji Hiroishi, Susono-shi (JP); Yukinobu Numata, Susono-shi (JP); Koji Suzuki, Susono-shi (JP)

(73) Assignee: ULVAC, INC., Chigasaki-shi (JP)

(21) Appl. No.: 13/990,816

(22) PCT Filed: Sep. 21, 2012
(86) PCT No.: PCT/JP2012/074242

§ 371 Date: May 31, 2013

(30) Foreign Application Priority Data
Sep. 30, 2011 (JP) 2011-217017

(51) Int. Cl. H01L 21/768; H01L 23/532; H01L 23/528

(52) U.S. Cl. CPC H01L 21/76846; H01L 23/528; H01L 23/53238; H01L 21/7685; H01L 21/76871
USPC 257/751; 438/653

(57) ABSTRACT

A method of manufacturing a semiconductor device includes: a groove portion formation step of forming a groove portion in a base; a barrier layer formation step of forming a barrier layer that covers at least an inner wall surface of the groove portion; a seed layer formation step of forming a seed layer that covers the barrier layer; and a burial step of burying a conductive material in an inside region of the seed layer, wherein the seed layer is made of Cu, and the conductive material is made of Cu.

### CROSS REFERENCE TO RELATED APPLICATIONS

This is the U.S. National Phase Application under 35 U.S.C. §371 of International Patent Application No. PCT/JP2012/074242 filed Sep. 21, 2012, which designated the United States and was published in a language other than English, which claims the benefit of Japanese Patent Application No. 2011-217017 filed on Sep. 30, 2011, both of them are fully incorporated by reference herein.

### TECHNICAL FIELD

The present invention relates to a method of manufacturing a semiconductor device and a semiconductor device. Specifically, the present invention relates to a technique for forming a fine wiring with a high degree of accuracy.

### BACKGROUND ART

Hitherto, as fine wiring materials of a semiconductor element and the like formed on a substrate, aluminum or aluminum alloys have been used. However, since aluminum has a low melting point and an inferior migration resistance, it is difficult to cope with the high integration and speeding-up of a semiconductor element.

For this reason, in recent years, copper has been used as a wiring material. Since copper has a higher melting point and a lower electrical resistivity than that of aluminum, copper is effective as an LSI wiring material. However, when copper is used as a wiring material, there is a problem in that it is difficult to achieve fine processing. For example, PTL 1 proposes a method of forming a groove in an insulating layer, burying copper in the inside of the groove, and then removing superfluous copper protruding from the groove, to form a copper wiring within the fine groove.

### CITATION LIST

### Patent Literature

[PTL 1] Japanese Unexamined Patent Application, First Publication No. H6-103681.

### SUMMARY OF INVENTION

### Technical Problem

However, in the invention disclosed in PTL 1, there is a problem in that it is difficult to bury copper in the inside of the groove without a gap.

That is, when copper is laminated in the inside of the groove by sputtering, the copper is not deposited up to the inside of the fine groove, but the copper is deposited only in the vicinity of an open end of the groove in a state where the inside of the groove remains a cavity.

In addition, when the inside of the groove is buried by melted copper using a reflow method, there is a problem in that wettability to the melted copper with respect to a barrier metal layer formed in the inner wall surface of the groove in advance deteriorates, and that copper is solidified in a state where a cavity occurs in the inside of the groove.

When a cavity occurs in a copper wiring formed in the inside of the groove in this manner, the resistance value of the copper wiring increases, which leads to a concern of disconnection.

An aspect of the present invention is contrived to solve the above-mentioned problems, and an object thereof is to provide a method of manufacturing a semiconductor device and a semiconductor device which are capable of obtaining a wiring having excellent conductivity by burying a conductive material in the inside of a fine groove portion without a gap.

### Solution to Problem

In order to solve the above-mentioned problems, the present invention adopts a method of manufacturing a semiconductor device and a semiconductor device as follows.

(1) According to an aspect of the present invention, a method of manufacturing a semiconductor device is provided, including: a groove portion formation step of forming a groove portion in a base; a barrier layer formation step of forming a barrier layer that covers at least an inner wall surface of the groove portion; a seed layer formation step of forming a seed layer that covers the barrier layer; and a burial step of burying a conductive material in an inside region of the seed layer, wherein the seed layer is made of Cu, and the conductive material is made of Cu.

(2) In the aspect of the above (1), the seed layer formation step may be a step of forming a Cu thin film that covers the barrier layer.

(3) In the aspect of the above (1) or (2), the burial step is a step of laminating the conductive material by a sputtering method so as to cover the seed layer.

(4) In the aspect according to any one of the above (1) to (3), the barrier layer is made of a material containing at least one of Ta, Ti, W, Ru, V, Co, and Nb.

(5) In the aspect according to any one of the above (1) to (4), the base is constituted by a semiconductor substrate and an insulating layer which is formed in one surface of the semiconductor substrate.

(6) According to another aspect of the present invention, a semiconductor device is provided, including: a groove portion which is formed in a base; a barrier layer that covers an inner wall surface of the groove portion; and a conductor which is buried in an inside region of the barrier layer, wherein the conductor is constituted by a first conductive layer, made of Cu, which covers the barrier layer and a second conductive layer, made of Cu, which is buried in an inside region of the first conductive layer.

### Advantageous Effects of Invention

According to the method of manufacturing a semiconductor device and the semiconductor device of an aspect of the present invention, in a seed layer formation step before a burial step of a conductive material, a seed layer that covers a barrier layer is formed in advance, thereby allowing wettability to be improved on a contact surface between the conductive material and the seed layer.

That is, the barrier layer, such as an oxide or a nitride, which is chiefly made of a metal compound has a tendency for fine irregularities to be generated on its surface and thus is short of surface smoothness. Cu, which is a conductive material, is short of wettability and flowability with respect to the barrier layer, which is chiefly made of a compound.

For this reason, as in the aspects of the present invention, the seed layer made of Cu is formed so as to cover the barrier layer, thereby allowing wettability and flowability to Cu, which is a conductive material, to be considerably enhanced. Therefore, even in a case of a groove portion having a high-aspect ratio, Cu, which is a conductive material, spreads uniformly throughout the entirety of the groove portion without generating a cavity in the inside thereof, and thus it is possible to obtain a high-accuracy conductor which has no local disconnection portion.

### BRIEF DESCRIPTION OF DRAWINGS

FIG. 1 is a main-part enlarged cross-sectional view illustrating a semiconductor device according to an embodiment of the present invention.

FIG. 2 is a main-part enlarged cross-sectional view illustrating a method of manufacturing a semiconductor device according to the embodiment of the present invention in a step-by-step manner.

FIG. 3 is a main-part enlarged cross-sectional view illustrating a method of manufacturing a semiconductor device according to the embodiment of the present invention in a step-by-step manner.

FIG. 4 is a schematic diagram illustrating an example of a sputtering apparatus (film formation apparatus) used in the embodiment of the present invention.

### DESCRIPTION OF EMBODIMENTS

Hereinafter, a method of manufacturing a semiconductor device according to an embodiment of the present invention and the semiconductor device will be described with reference to the accompanying drawings. Meanwhile, the present embodiment is one which is described by way of example in order to better understand the gist of the present invention, although the present invention is not limited thereto, except as otherwise noted. In addition, in the drawings used in the following description, the portions which are chief parts may be enlarged, for convenience, in order to easily understand the features of the present invention, and the dimension ratios and the like for each of the components are not limited to the same dimensions as real ones.

(Semiconductor Device)

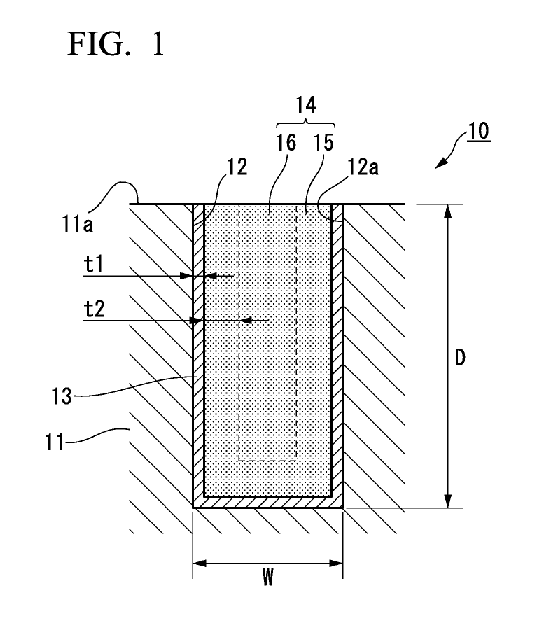

FIG. 1 is a main-part enlarged cross-sectional view illustrating a semiconductor device according to an embodiment of the present invention.

A semiconductor device 10 includes a base 11. The base 11 is formed of an insulating substrate, for example, a glass substrate, a resin substrate, or the like. Meanwhile, a semiconductor element or the like, for example, may be formed in a portion of the base 11.

A groove portion (trench) 12 is formed in one surface 11a of the base 11. The groove portion 12 is formed of, for example, a deep and fine groove, having a small width, which is dug down in the depthwise direction of the base 11 from the one surface 11a of the base 11. The width W of the bottom of the groove portion 12 is formed to be, for example, approximately 20 nm to 50 nm. In addition, the depth D of the groove portion 12 is formed to be, for example, approximately 80 nm to 200 nm. A conductor, for example, constituting a circuit wiring of the semiconductor element is formed in an inside region of such a groove portion 12.

A barrier layer (barrier metal) 13 is formed in the groove portion 12 so as to cover an inner wall surface 12a. The barrier layer 13 is formed of, for example, a Ta (tantalum) nitride, a Ta silicide, a Ta carbide, a Ti (titanium) nitride, a Ti silicide, a Ti carbide, a W (tungsten) nitride, a W silicide, a W carbide, Ru (ruthenium), a Ru oxide, a V (vanadium) oxide, a Co (cobalt) oxide, a Nb (niobium) oxide, or the like.

The barrier layer (barrier metal) 13 is formed so that the thickness t1 thereof is, for example, approximately 1 nm to 3 nm.

Further, a conductor 14 made of a conductive material is formed in an inside region of the barrier layer (barrier metal) 13. The conductor 14 is constituted by a first conductive layer 15 formed to cover the barrier layer (barrier metal) 13, and a second conductive layer 16 formed in an inside region of the first conductive layer 15.

The conductor 14 serves as, for example, a circuit wiring of the semiconductor element formed in the base 11.

The first conductive layer (seed layer) 15 is made of Cu (copper). The first conductive layer 15 increases wettability to the second conductive layer 16, made of Cu (copper), which is formed in the inside of the first conductive layer 15.

The first conductive layer 15 is preferably formed so that the thickness t2 thereof is 3 nm to 8 nm, and is more preferably formed so that the thickness is 5 nm to 6 nm.

Even when the second conductive layer 16 is formed in a case where the thickness t2 of the first conductive layer 15 is less than 3 nm, there is a concern that the inside region of the groove portion 12 in the base 11 may not be able to be completely filled with the conductor 14. On the other hand, when the thickness t2 of the first conductive layer 15 exceeds (W−2T1)/2, there is a concern that the second conductive layer 16 may not be able to be formed.

The second conductive layer 16 is formed in the inside region of the first conductive layer 15 in the groove portion 12. The second conductive layer 16 is made of Cu (copper). The second conductive layer 16 is formed in the inside region of the first conductive layer 15 by depositing a conductive material (Cu) using a sputtering method.

The second conductive layer 16 is preferably formed on the one surface 11a of the base 11 so that the thickness thereof is equal to or more than 10 nm, and is more preferably formed so that the thickness is 15 nm to 55 nm.

When the thickness of the second conductive layer 16 formed on the one surface 11a of the base 11 is less than 10 nm, there is a concern that the second conductive layer 16 may not be able to be completely filled in the inside region of the first conductive layer 15.

According to the semiconductor device 10 having such a configuration, the conductor 14 constituted by the first conductive layer 15 made of Cu and the second conductive layer 16 made of Cu is formed in the inside region of the barrier layer (barrier metal) 13, thereby allowing a conductive material to be buried in the inside of the groove portion 12 without a gap during the formation of the conductor 14. Thus, it is possible to realize the semiconductor device 10 including the conductor (circuit wiring) 14, made of Cu, which has a uniform electric resistance and no concern of disconnection or the like.

(Method of Manufacturing Semiconductor Device)

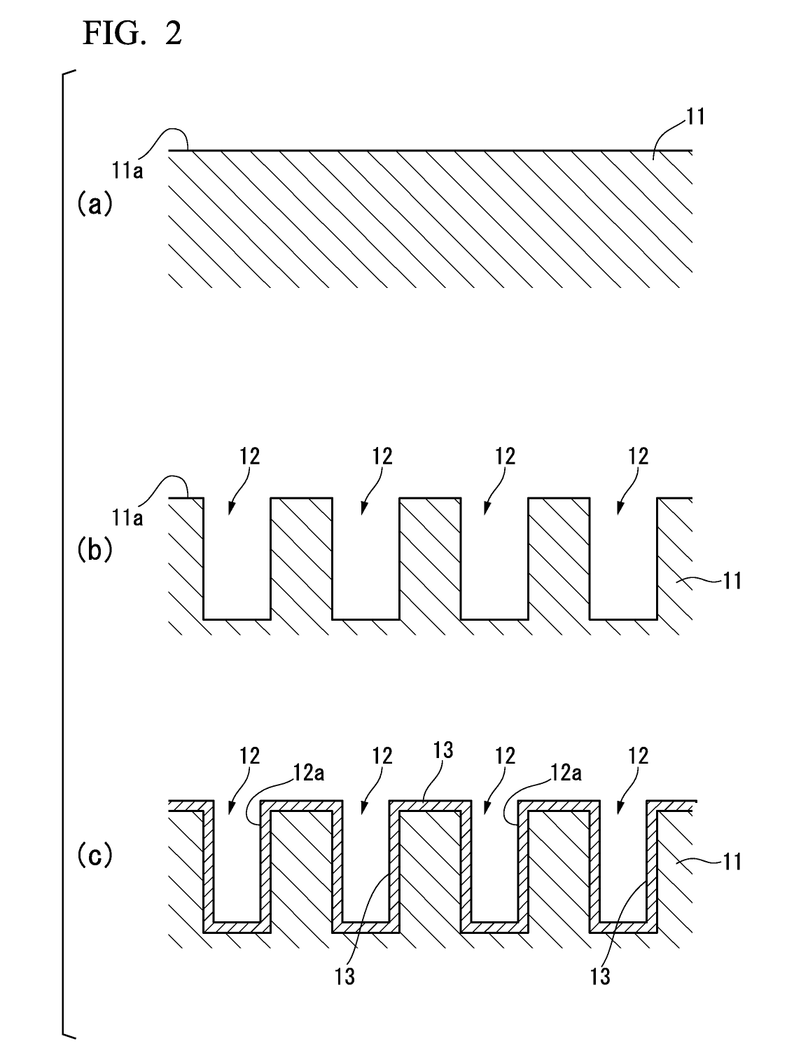

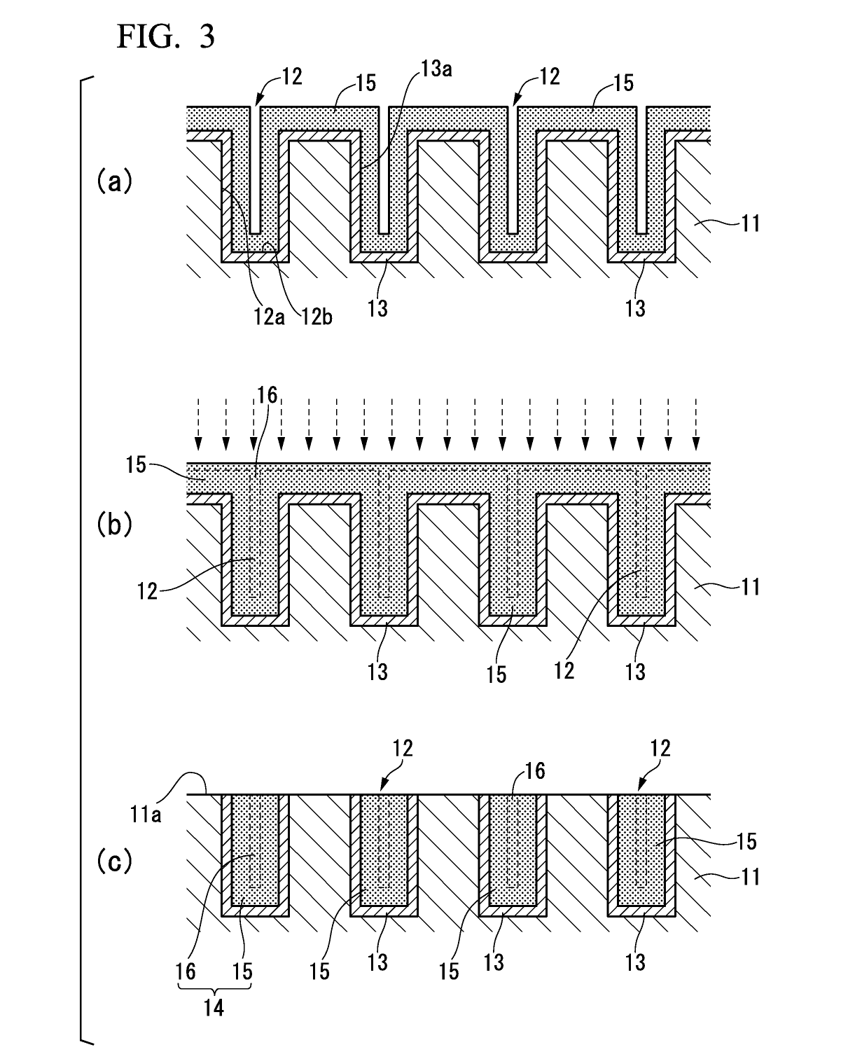

FIGS. 2 and 3 are main-part enlarged cross-sectional views illustrating a method of manufacturing a semiconductor device according to the embodiment of the present invention in a step-by-step manner.

When the semiconductor device according to the embodiment of the present invention is manufactured, the base 11 is first prepared (see FIG. 2(a)). As the base 11, an insulating substrate and a semiconductor substrate are used. The insulating substrate includes, for example, a glass substrate and a resin substrate. In addition, the semiconductor substrate includes, for example, a silicon wafer, a SiC wafer, and the like. A semiconductor element (not shown), for example, is formed in the base 11 in advance.

Next, the groove portion 12 having a predetermined depth is formed in one surface 11a of the base 11 (see FIG. 2(b): groove portion formation step). The groove portion 12 is formed to have, for example, a pattern which is in the shape of a circuit wiring of the semiconductor element. As a method of forming the groove portion 12 in the one surface 11a of the base 11, for example, an etching process using photolithography or a process using laser light can be used.

Next, the barrier layer (barrier metal) 13 having a predetermined thickness is formed in the one surface 11a of the base 11 including the inner wall surface 12a of the groove portion 12 (see FIG. 2(c): barrier layer formation step). The barrier layer (barrier metal) 13 is formed using, for example, a material including at least one of Ta, Ti, W, Ru, V, Co, an Nb. The barrier layer 13 is preferably formed using, for example, a sputtering method. In addition, the barrier layer (barrier metal) 13 is formed so that the thickness t1 thereof is, for example, approximately 1 nm to 3 nm.

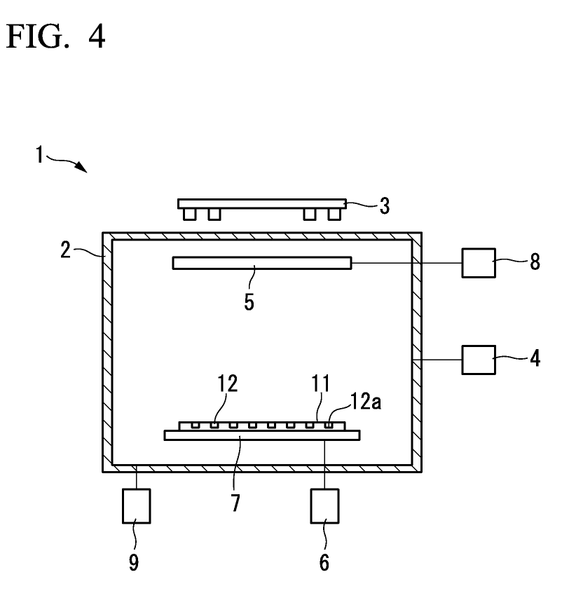

FIG. 4 is a diagram illustrating an example of a sputtering apparatus (film formation apparatus) used in the formation of a barrier layer.

A sputtering apparatus (film formation apparatus) 1 includes a vacuum chamber 2, and a substrate holder 7 and a target 5 which are disposed in the inside of the vacuum chamber 2.

A vacuum exhaust system 9 and a gas supply system 4 are connected to the vacuum chamber 2, the inside of the vacuum chamber 2 is vacuum-exhausted, and a sputtering gas and a reaction gas which contains nitrogen or oxygen in a chemical structure are introduced from the gas supply system 4 while being vacuum-exhausted (for example, when the reaction gas is oxygen, the flow rate is equal to or more than 0.1 sccm and equal to or less than 5 sccm), to form a film formation atmosphere (for example, the total pressure thereof is equal to or less than 10⁴ Pa) lower than atmospheric pressure in the inside of the vacuum chamber 2.

One surface 11a side of the base 11 in which the groove portion 12 is formed is held by the substrate holder 7 with the one surface being directed toward the target 5. A sputtering power supply 8 and a bias power supply 6 are disposed outside the vacuum chamber 2, the target 5 is connected to the sputtering power supply 8, and the substrate holder 7 is connected to the bias power supply 6.

Magnetic field formation means 3 is disposed outside the vacuum chamber 2, and the vacuum chamber 2 is connected to a ground potential. When a negative voltage is applied to the target 5 while maintaining the film formation atmosphere inside the vacuum chamber 2, magnetron sputtering is performed on the target 5. The target 5 is formed primarily of the above-mentioned formation material of the barrier layer (barrier metal) 13.

When magnetron sputtering is performed on the target 5, the formation material of the barrier layer 13 is then emitted as sputtered particles.

The emitted sputtered particles and the reaction gas are incident on the one surface 11a of the base 11 in which the groove portion 12 is formed, and the barrier layer 13 is formed so as to cover the one surface 11a of the base 11 including the inner wall surface 12a of the groove portion 12.

Next, the seed layer (first conductive layer) 15 is formed so as to cover the barrier layer 13 (see FIG. 3(a): seed layer (first conductive layer) formation step). The seed layer 15 is made of Cu. The seed layer 15 is formed by a sputtering method similarly to the above-mentioned barrier layer 13.

A method of forming the seed layer 15 using the sputtering apparatus (film formation apparatus) 1 will be described.

First, in a state where the base 11 is disposed on the substrate holder 7, the inside of the vacuum chamber 2 is vacuum-exhausted by the vacuum exhaust system 9, and a sputtering gas and a reaction gas which contains nitrogen or oxygen in a chemical structure are introduced from the gas supply system 4 while being vacuum-exhausted (for example, when the reaction gas is oxygen, the flow rate thereof is equal to or more than 0.1 sccm and equal to or less than 5 sccm), to form a film formation atmosphere (for example, the total pressure thereof is equal to or less than 10⁴ Pa) lower than atmospheric pressure in the inside of the vacuum chamber 2.

After the sputtering gas is introduced, and the inside of the vacuum chamber 2 is stabilized to a predetermined pressure (for example, a pressure of approximately 4.0×10⁻² Pa), the sputtering power supply 8 is started up, and a negative voltage is applied to a cathode electrode (not shown). Thereby, electrical discharge is started, and plasma is generated in the vicinity of the surface of the target 5, using the target 5 as Cu.

After film formation through sputtering is performed for a predetermined time, and a copper thin film is formed so as to cover the barrier layer 13, the base 11 is unloaded from the vacuum chamber 2.

Meanwhile, temperature regulation means (not shown) is provided within the substrate holder 7 of the above-mentioned sputtering apparatus 1, and the temperature of the base 11 is regulated to a predetermined temperature when the copper thin film is formed (for example, −20° C.).

In the sputtering apparatus 1, the magnetic field formation means 3 is configured to be capable of being moved and rotated parallel to the surface of the target 5, and a sputtered region (erosion region) on the surface of the target 5 can be formed at an arbitrary position on the target.

Next, the second conductive layer 16 is formed by burying a conductive material in an inside region of the seed layer 15 (see FIG. 3(b): second conductive layer formation step and burial step). The second conductive layer 16 is made of Cu. The second conductive layer 16 is formed by a sputtering method similarly to the above-mentioned seed layer 15.

When the conductive material is buried in the inside region of the seed layer 15 by a sputtering method, a conductive material made of Cu is deposited on the one surface 11a side of the base 11 including the inside region of the seed layer 15, using the target 5 as Cu, using the sputtering apparatus (film formation apparatus) 1 shown in FIG. 4.

Meanwhile, when the second conductive layer 16 is formed, the temperature of the base 11 is set to 100° C. to 400° C. by the temperature regulation means (not shown) provided within the substrate holder 7.

Even when a conductive material is buried by such a sputtering method, adhesion between the deposited Cu and the seed layer 15 increases by the formation of the seed layer 15 made of Cu, and thus Cu can be uniformly deposited in the inside of the seed layer 15 without generating a cavity.

Thereafter, the barrier layer 13, the seed layer 15 and the second conductive layer 16 which are laminated in the one surface 11a of the base 11 except for the groove portion 12 are removed (see FIG. 3(c)). Thereby, the conductor 14 that buries the groove portion 12, that is, the circuit wiring is formed for each groove portion 12.

### EXAMPLES

Hereinafter, the embodiment of the present invention will be described in more detail through experimental examples, but the present invention is not limited to the following experimental examples.

### Experimental Example 1

A silicon substrate with a silicon oxide film having a thickness of 0.775 mm was prepared as a base.

Next, a groove portion having a depth of 100 nm was formed on one surface of the base by an etching process using photolithography.

Next, a barrier layer, made of Ta, having a thickness of 3 nm was formed in the one surface of the base including an inner wall surface of the groove portion by a sputtering method.

Next, a copper thin film of a seed layer (first conductive layer), made of Cu, having a thickness of 15 nm was formed by a sputtering method so as to cover the barrier layer. When the copper thin film was formed, the temperature of the base was regulated to −20° C.

Next, a second conductive layer was formed by burying Cu in an inside region of the seed layer by a sputtering method. The temperature of the base was regulated to 400° C. at the time of formation of the second conductive layer.

Here, the second conductive layer was formed so that the thickness of the second conductive layer formed on the one surface of the base was 0 nm.

After the second conductive layer was formed, a filling rate of the groove portion (rate at which the groove portion is filled with a conductor constituted by the first conductive layer and the second conductive layer, or vol %) in the base in which a conductor constituted by the seed layer (first conductive layer) and the second conductive layer was formed was examined using a scanning electron microscope (SEM).

Meanwhile, a case where the filling rate was equal to or more than 90% was evaluated as O, a case where the filling rate was equal to or more than 80% and less than 90% was evaluated as Δ, and a case where the filling rate was less than 80% was evaluated as x.

The result is shown in Table 1.

### Experimental Example 2

The conductor was filled into the groove portion of the base similarly to Experimental Example 1 except that the second conductive layer was formed so that the thickness of the second conductive layer formed on the one surface of the base was 20 nm.

In addition, the filling rate of the groove portion was examined similarly to Experimental Example 1.

The result is shown in Table 1.

### Experimental Example 3

The conductor was filled into the groove portion of the base similarly to Experimental Example 1 except that the second conductive layer was formed so that the thickness of the second conductive layer formed on the one surface of the base was 40 nm.

In addition, the filling rate of the groove portion was examined similarly to Experimental Example 1.

The result is shown in Table 1.

### Experimental Example 4

The conductor was filled into the groove portion of the base similarly to

Experimental Example 1 except that the second conductive layer was formed so that the thickness of the second conductive layer formed on the one surface of the base was 60 nm.

In addition, the filling rate of the groove portion was examined similarly to Experimental Example 1.

The result is shown in Table 1.

### Experimental Example 5

The conductor was filled into the groove portion of the base similarly to Experimental Example 1 except that the temperature of the base was regulated to 300° C. at the time of the formation of the second conductive layer.

In addition, the filling rate of the groove portion was examined similarly to Experimental Example 1.

The result is shown in Table 1.

### Experimental Example 6

The conductor was filled into the groove portion of the base similarly to Experimental Example 1 except that the second conductive layer was formed so that the temperature of the base was regulated to 300° C. at the time of the formation of the second conductive layer, and the thickness of the second conductive layer formed on the one surface of the base was 20 nm.

In addition, the filling rate of the groove portion was examined similarly to Experimental Example 1.

The result is shown in Table 1.

### Experimental Example 7

The conductor was filled into the groove portion of the base similarly to Experimental Example 1 except that the second conductive layer was formed so that the temperature of the base was regulated to 300° C. at the time of the formation of the second conductive layer, and the thickness of the second conductive layer formed on the one surface of the base was 40 nm.

In addition, the filling rate of the groove portion was examined similarly to Experimental Example 1.

The result is shown in Table 1.

### Experimental Example 8

The conductor was filled into the groove portion of the base similarly to Experimental Example 1 except that the second conductive layer was formed so that the temperature of the base was regulated to 300° C. at the time of the formation of the second conductive layer, and the thickness of the second conductive layer formed on the one surface of the base was 60 nm.

In addition, the filling rate of the groove portion was examined similarly to Experimental Example 1.

The result is shown in Table 1.

### Experimental Example 9

The conductor was filled into the groove portion of the base similarly to Experimental Example 1 except that the seed layer (first conductive layer) having a thickness of 25 nm was formed.

In addition, the filling rate of the groove portion was examined similarly to Experimental Example 1.

The result is shown in Table 2.

### Experimental Example 10

The conductor was filled into the groove portion of the base similarly to

Experimental Example 1 except that the seed layer (first conductive layer) having a thickness of 25 nm was formed, and that the second conductive layer was formed so that the thickness of the second conductive layer formed on the one surface of the base was 20 nm.

In addition, the filling rate of the groove portion was examined similarly to Experimental Example 1.

The result is shown in Table 2.

### Experimental Example 11

The conductor was filled into the groove portion of the base similarly to Experimental Example 1 except that the seed layer (first conductive layer) having a thickness of 25 nm was formed, and that the second conductive layer was formed so that the thickness of the second conductive layer formed on the one surface of the base was 40 nm.

In addition, the filling rate of the groove portion was examined similarly to Experimental Example 1.

The result is shown in Table 2.

### Experimental Example 12

The conductor was filled into the groove portion of the base similarly to Experimental Example 1 except that the seed layer (first conductive layer) having a thickness of 25 nm was formed, and that the second conductive layer was formed so that the thickness of the second conductive layer formed on the one surface of the base was 60 nm.

In addition, the filling rate of the groove portion was examined similarly to Experimental Example 1.

The result is shown in Table 2.

### Experimental Example 13

The conductor was filled into the groove portion of the base similarly to Experimental Example 1 except that the seed layer (first conductive layer) having a thickness of 25 nm was formed, and that the temperature of the base was regulated to 300° C. at the time of the formation of the second conductive layer.

In addition, the filling rate of the groove portion was examined similarly to Experimental Example 1.

The result is shown in Table 2.

### Experimental Example 14

The conductor was filled into the groove portion of the base similarly to Experimental Example 1 except that the seed layer (first conductive layer) having a thickness of 25 nm was formed, the temperature of the base was regulated to 300° C. at the time of the formation of the second conductive layer, and that the second conductive layer was formed so that the thickness of the second conductive layer formed on the one surface of the base was 20 nm.

In addition, the filling rate of the groove portion was examined similarly to Experimental Example 1.

The result is shown in Table 2.

### Experimental Example 15

The conductor was filled into the groove portion of the base similarly to Experimental Example 1 except that the seed layer (first conductive layer) having a thickness of 25 nm was formed, the temperature of the base was regulated to 300° C. at the time of the formation of the second conductive layer, and that the second conductive layer was formed so that the thickness of the second conductive layer formed on the one surface of the base was 40 nm.

In addition, the filling rate of the groove portion was examined similarly to Experimental Example 1.

The result is shown in Table 2.

### Experimental Example 16

The conductor was filled into the groove portion of the base similarly to Experimental Example 1 except that the seed layer (first conductive layer) having a thickness of 25 nm was formed, the temperature of the base was regulated to 300° C. at the time of the formation of the second conductive layer, and that the second conductive layer was formed so that the thickness of the second conductive layer formed on the one surface of the base was 60 nm.

In addition, the filling rate of the groove portion was examined similarly to Experimental Example 1.

The result is shown in Table 2.

### Experimental Example 17

The conductor was filled into the groove portion of the base similarly to

Experimental Example 1 except that the seed layer (first conductive layer) having a thickness of 25 nm was formed, the temperature of the base was regulated to 250° C. at the time of the formation of the second conductive layer, and that the second conductive layer was formed so that the thickness of the second conductive layer formed on the one surface of the base was 20 nm.

In addition, the filling rate of the groove portion was examined similarly to Experimental Example 1.

The result is shown in Table 2.

### Experimental Example 18

The conductor was filled into the groove portion of the base similarly to

Experimental Example 1 except that the seed layer (first conductive layer) having a thickness of 25 nm was formed, the temperature of the base was regulated to 250° C. at the time of the formation of the second conductive layer, and that the second conductive layer was formed so that the thickness of the second conductive layer formed on the one surface of the base was 40 nm.

In addition, the filling rate of the groove portion was examined similarly to Experimental Example 1.

The result is shown in Table 2.

### Experimental Example 19

The conductor was filled into the groove portion of the base similarly to Experimental Example 1 except that the seed layer (first conductive layer) having a thickness of 25 nm was formed, the temperature of the base was regulated to 250° C. at the time of the formation of the second conductive layer, and that the second conductive layer was formed so that the thickness of the second conductive layer formed on the one surface of the base was 60 nm.

In addition, the filling rate of the groove portion was examined similarly to Experimental Example 1.

The result is shown in Table 2.

### Experimental Example 20

The conductor was filled into the groove portion of the base similarly to Experimental Example 1 except that the seed layer (first conductive layer) having a thickness of 35 nm was formed.

In addition, the filling rate of the groove portion was examined similarly to Experimental Example 1.

The result is shown in Table 3.

### Experimental Example 21

The conductor was filled into the groove portion of the base similarly to Experimental Example 1 except that the seed layer (first conductive layer) having a thickness of 35 nm was formed, and that the second conductive layer was formed so that the thickness of the second conductive layer formed on the one surface of the base was 20 nm.

In addition, the filling rate of the groove portion was examined similarly to Experimental Example 1.

The result is shown in Table 3.

Experimental Example 22

The conductor was filled into the groove portion of the base similarly to Experimental Example 1 except that the seed layer (first conductive layer) having a thickness of 35 nm was formed, and that the second conductive layer was formed so that the thickness of the second conductive layer formed on the one surface of the base was 40 nm.

In addition, the filling rate of the groove portion was examined similarly to Experimental Example 1.

The result is shown in Table 3.

### Experimental Example 23

The conductor was filled into the groove portion of the base similarly to Experimental Example 1 except that the seed layer (first conductive layer) having a thickness of 35 nm was formed, and that the second conductive layer was formed so that the thickness of the second conductive layer formed on the one surface of the base was 50 nm.

In addition, the filling rate of the groove portion was examined similarly to Experimental Example 1.

The result is shown in Table 3.

### Experimental Example 24

The conductor was filled into the groove portion of the base similarly to Experimental Example 1 except that the seed layer (first conductive layer) having a thickness of 35 nm was formed, and that the second conductive layer was formed so that the thickness of the second conductive layer formed on the one surface of the base was 60 nm.

In addition, the filling rate of the groove portion was examined similarly to Experimental Example 1.

The result is shown in Table 3.

### Experimental Example 25

The conductor was filled into the groove portion of the base similarly to Experimental Example 1 except that the seed layer (first conductive layer) having a thickness of 35 nm was formed, and that the temperature of the base was regulated to 300° C. at the time of the formation of the second conductive layer.

In addition, the filling rate of the groove portion was examined similarly to Experimental Example 1.

The result is shown in Table 3.

### Experimental Example 26

The conductor was filled into the groove portion of the base similarly to Experimental Example 1 except that the seed layer (first conductive layer) having a thickness of 35 nm was formed, the temperature of the base was regulated to 300° C. at the time of the formation of the second conductive layer, and that the second conductive layer was formed so that the thickness of the second conductive layer formed on the one surface of the base was 20 nm.

In addition, the filling rate of the groove portion was examined similarly to Experimental Example 1.

The result is shown in Table 3.

### Experimental Example 27

The conductor was filled into the groove portion of the base similarly to Experimental Example 1 except that the seed layer (first conductive layer) having a thickness of 35 nm was formed, the temperature of the base was regulated to 300° C. at the time of the formation of the second conductive layer, and that the second conductive layer was formed so that the thickness of the second conductive layer formed on the one surface of the base was 40 nm.

In addition, the filling rate of the groove portion was examined similarly to Experimental Example 1.

The result is shown in Table 3.

### Experimental Example 28

The conductor was filled into the groove portion of the base similarly to Experimental Example 1 except that the seed layer (first conductive layer) having a thickness of 35 nm was formed, the temperature of the base was regulated to 300° C. at the time of the formation of the second conductive layer, and that the second conductive layer was form so that the thickness of the second conductive layer formed on the one surface of the base was 50 nm.

In addition, the filling rate of the groove portion was examined similarly to Experimental Example 1.

The result is shown in Table 3.

### Experimental Example 29

The conductor was filled into the groove portion of the base similarly to Experimental Example 1 except that the seed layer (first conductive layer) having a thickness of 35 nm was formed, the temperature of the base was regulated to 300° C. at the time of the formation of the second conductive layer, and that the second conductive layer was formed so that the thickness of the second conductive layer formed on the one surface of the base was 60 nm.

In addition, the filling rate of the groove portion was examined similarly to Experimental Example 1.

The result is shown in Table 3.

TABLE 1

| Second Conductive Layer | | | | |
|---|---|---|---|---|
| Formation | Thickness of Second Conductive Layer (nm) | | | |
| Temperature (° C.) | 0 | 20 | 40 | 60 |
| 400 | x | x | x | x |
| 300 | x | x | x | x |

TABLE 2

| Second Conductive Layer | | | | |
|---|---|---|---|---|
| Formation | Thickness of Second Conductive Layer (nm) | | | |
| Temperature (° C.) | 0 | 20 | 40 | 60 |
| 400 | x | x | x | x |
| 300 | x | Δ | ∘ | ∘ |
| 250 | — | x | Δ | x |

TABLE 3

| Second Conductive Layer | | | | | |
|---|---|---|---|---|---|
| Formation | Thickness of Second Conductive Layer (nm) | | | | |
| Temperature (° C.) | 0 | 20 | 40 | 50 | 60 |
| 400 | Δ | Δ | ∘ | ∘ | ∘ |
| 300 | x | Δ | ∘ | Δ | ∘ |

From the result of Table 1, when the thickness of the seed layer (first conductive layer) was 15 nm, it was found that the conductor constituted by the first conductive layer and the second conductive layer could not be sufficiently filled into the groove portion.

From the result of Table 2, when the thickness of the seed layer (first conductive layer) was set to 25 nm, and the temperature of the base at the time of the formation of the second conductive layer was set to 400° C., it was found that the conductor constituted by the first conductive layer and the second conductive layer could not be sufficiently filled into the groove portion. In addition, when the thickness of the seed layer (first conductive layer) was set to 25 nm, and the temperature of the base at the time of the formation of the second conductive layer was set to 300° C., it was found that the conductor constituted by the first conductive layer and the second conductive layer could be sufficiently filled into the groove portion by forming the second conductive layer so that the thickness of the second conductive layer formed on the one surface of the base was equal to or more than 40 nm.

From the result of Table 3, when the thickness of the seed layer (first conductive layer) was set to 35 nm, and the temperature of the base at the time of the formation of the second conductive layer was set to 400° C., it was found that the conductor constituted by the first conductive layer and the second conductive layer could be sufficiently filled into the groove portion by forming the second conductive layer so that the thickness of the second conductive layer formed on the one surface of the base was equal to or more than 40 nm. In addition, when the thickness of the seed layer (first conductive layer) was set to 35 nm, and the temperature of the base at the time of the formation of the second conductive layer was set to 300° C., it was found that the conductor constituted by the first conductive layer and the second conductive layer could be sufficiently filled into the groove portion by forming the second conductive layer so that the thickness of the second conductive layer formed on the one surface of the base was equal to or more than 40 nm.

### REFERENCE SIGNS LIST

10: SEMICONDUCTOR DEVICE
11: BASE
12: GROOVE PORTION (TRENCH)
13: BARRIER LAYER (BARRIER METAL)
14: CONDUCTOR (CIRCUIT WIRING)
15: FIRST CONDUCTIVE LAYER
16: SECOND CONDUCTIVE LAYER

What is claimed is:

1-6. (canceled)

7. A method of manufacturing a semiconductor device, comprising:
a groove portion formation step of forming a groove portion in a base;
a barrier layer formation step of forming a barrier layer that covers at least an inner wall surface of the groove portion;
a seed layer formation step of forming a seed layer that covers the barrier layer; and
a burial step of burying a conductive material in an inside region of the seed layer,
wherein the seed layer is made of Cu, the conductive material is made of Cu, the seed layer formation step and the burial step are performed by a sputtering method, and a temperature of the base in the burial step is 250° C. to 400° C.

8. The method of manufacturing a semiconductor device according to claim 7, wherein the seed layer formation step is a step of forming a Cu thin film that covers the barrier layer, and a temperature of the base in the seed layer formation step is a lower temperature than in the burial step.

9. The method of manufacturing a semiconductor device according to claim 7, wherein a thickness of the seed in the inside of the groove portion is 3 to 8 nm.

10. The method of manufacturing a semiconductor device according to claim 8, wherein a thickness of the seed in the inside of the groove portion is 3 to 8 nm.

11. The method of manufacturing a semiconductor device according to claim 7, wherein the barrier layer is made of a material containing at least one of Ta, Ti, W, Ru, V, Co, and Nb.

12. The method of manufacturing a semiconductor device according to claim 7, wherein the base is constituted by a semiconductor substrate and an insulating layer which is formed in one surface of the semiconductor substrate.

13. A semiconductor device comprising:
a groove portion which is formed in a base;
a barrier layer that covers an inner wall surface of the groove portion; and
a conductor which is buried in an inside region of the barrier layer,
wherein the conductor is constituted by a first conductive layer, made of Cu, which covers the barrier layer and a second conductive layer, made of Cu, which is buried in an inside region of the first conductive layer.
